(19) United States
(12) Patent Application Publication
(10) Pub. No.: US 2005/0139939 A1
(43) Pub. Date: Jun. 30, 2005

(54) Wafer protection device

(75) Inventors: Hung-Sheng Hu, Kaohsiung (TW); Wei-Lin Chen, Taipei (TW)

Correspondence Address: Richard P. Berg;c/o LADAS & PARRY, Suite 2100, 5670 Wilshire Boulevard, Los Angeles, CA, 90036-5679, US

(73) Assignee: BENO CORPORATION

(21) Appl. No.: 11/021,298

(22) Filed: Dec. 22, 2004

Related U.S. Application Data
(62) Division of application No. 10/339,034, filed on Jan. 8, 2003.

(30) Foreign Application Priority Data
Jan. 10, 2002 (TW) 91100229

(51) Int. Cl. H01L 21/00; H01L 27/14; H01L 29/82; H01L 29/84

(52) U.S. Cl. 257/414; 438/48

(57) ABSTRACT

A wafer protection device. The wafer has a first surface etched with an etching fluid and a second surface, and the wafer protection device is applied to the wafer to prevent a specific area on the second surface of the wafer from etching. The wafer protection device has a body and a pressure modulating device. The body covers the specific area of the wafer and provides an isolated cavity between the body and the specific area to prevent the specific area from contacting the etching fluid, and the pressure modulating device is provided on the body and connected to the isolated cavity to modulate pressure in the isolated cavity.

### BACKGROUND OF THE INVENTION

1. Field of the Invention

The present invention relates to a wafer protection device, and particularly to a wafer protection device to be applied in etching of the micro-electromechanical system (MEMS).

2. Description of the Related Art

Semiconductor and MEMS techniques have been widely developed in recent years. In MEMS techniques, etching is generally applied in bulk micro-machining of the silicon substrate. Since etching time is related to the thickness of the substrate, such as Si-wafer, the substrate must be disposed in the etching fluid for a certain period of time. In this case, etching is generally performed at the beginning of the manufacturing process, so that the circuit layout on the wafer is not affected by etching.

However, in the above-mentioned etching process, the wafer must be disposed in the etching fluid for a certain period of time to perform bulk etching. In this certain period of time, metal atoms contained in the etching fluid are diffused into the wafer, which may further induce furnace contamination.

On the other hand, the bulk etching process produces throughholes or deep canals on the wafer, which significantly reduces the strength and resilience of the wafer and increases wafer fracture possibilities in the subsequent manufacturing processes.

In conventional bulk wafer etching, alkali fluids such as KOH or TMAH are generally applied as the etching fluid. In this case, the alkali etching fluid has a relatively high etching rate to the passivation layer material, such as silicon nitride or silicon oxide, generally applied on the wafer. That is, the passivation layer material is unable to prevent circuit layout on the wafer from being affected by etching.

Accordingly, a conventional wafer protection method in etching applies a corrosion-resistant wafer protection device to separate a selected area of the circuit plotting on the wafer from the etching fluid by providing a sealed cavity between the wafer protection device and the selected area. Since the conventional wafer protection device is corrosion-resistant, the etching fluid is prevented from contacting the area on the wafer.

In the above-mentioned conventional wafer protection device, the selected area on the wafer is optimally protected from the etching fluid at room temperature. However, etching is generally performed at a higher operating temperature, such as 85° C. In this case, gas fills the sealed cavity provided by the wafer protection device. Since the sealed cavity has a fixed volume, the pressure P of the gas in the sealed cavity is in proportion to the temperature T of the gas according to the ideal gas equation PV=nRT. That is, if the gas in the sealed cavity has a pressure of 1 atm at room temperature, the pressure of the gas at the operating temperature (85° C.) of etching becomes 1.2 atm. Since the strength and resilience of the wafer are reduced by etching, fractures due to the increased pressure may occur.

Further, in this case, even if fractures do not occur, the gas in the sealed cavity cools when etching ends, and the pressure of the gas is decreased to the ambient pressure, which again reduces the strength and resilience of the wafer. That is, the wafer sustains a pressure pulse in the etching process, which may induce fracture or creeping fatigue in the wafer.

### SUMMARY OF THE INVENTION

In view of this, the present invention relates to a wafer protection device to be applied in the etching process of the micro-electromechanical system (MEMS). The wafer protection device of the present invention not only isolates a specific protected area on the wafer from the etching fluid, but modulates the pressure in the isolated cavity between the wafer protection device and the protected area of the wafer, so that the pressure in the isolated cavity is kept at a certain value regardless of the temperature, protecting the wafer from fracture or creeping fatigue due to the pressure change.

The present invention discloses a wafer protection device for a wafer. The wafer has a first surface etched with an etching fluid and a second surface, and the wafer protection device is applied to prevent a specific area on the second surface of the wafer from etching. The wafer protection device has a body and a pressure modulating device. The body covers the specific area of the wafer and provides an isolated cavity between the body and the specific area to prevent the specific area from contacting the etching fluid, and the pressure modulating device is provided on the body and connected to the isolated cavity to modulate pressure in the isolated cavity.

In the wafer protection device of the present invention, the body may have a base, an elastic device between the base and the wafer, and a fixing device provided on the base for applying force to the elastic device toward the wafer to deform the elastic device, providing a seal.

Further, the present invention also discloses a method of etching a wafer, which comprises the steps of: providing a wafer protection device for the wafer; positioning the wafer on the wafer protection device; disposing the wafer protection device into etching fluid, wherein the wafer protection device protects a specific area on the wafer from etching; and modulating the interior pressure of the wafer protection device.

### BRIEF DESCRIPTION OF THE DRAWINGS

The present invention is more fully understood by reading the subsequent detailed description in conjunction with the examples and references made to the accompanying drawings, wherein:

FIG. 1 is a schematic view showing the first embodiment of the wafer protection device of the present invention;

FIG. 2a is a schematic view showing the second embodiment of the wafer protection device of the present invention;

FIG. 2b is a schematic view showing the third embodiment of the wafer protection device of the present invention;

FIG. 2c is a schematic view showing the fourth embodiment of the wafer protection device of the present invention;

FIG. 3 is a schematic view showing the fifth embodiment of the wafer protection device of the present invention;

FIG. 4a is a schematic view showing the sixth embodiment of the wafer protection device of the present invention;

FIG. 4b is a schematic view showing an embodiment of the outlet valve in FIG. 4a;

FIG. 4c is a schematic view showing an embodiment of the inlet valve in FIG. 4a; and

FIG. 5 is a schematic view showing the seventh embodiment of the wafer protection device of the present invention.

### DETAILED DESCRIPTION OF THE INVENTION

### THE FIRST EMBODIMENT

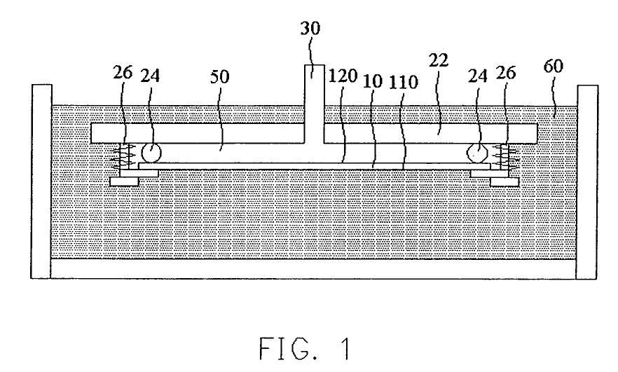

An embodiment of the wafer protection device of the present invention is hereinafter described in detail with reference to FIG. 1.

The wafer protection device of the present invention is applied to a wafer 10, in which the wafer 10 has a first surface 110 etched with an etching fluid 60 and a second surface 120, so that the wafer protection device prevents a specific area on the second surface 120 of the wafer 10 from etching.

The wafer protection device of the present invention has a body and a pressure modulating device. The body covers the specific area on the second surface 120 of the wafer 10 and provides an isolated cavity 50 between the body and the specific area to prevent the specific area from contacting the etching fluid 60. The specific area of the wafer 10 is generally provided with circuit layout that requires protection from etching. Further, the pressure modulating device is provided on the body and connected to the isolated cavity 50 to modulate pressure in the isolated cavity 50.

In this embodiment, the body has a base 22, an elastic device 24, and a fixing device 26, as shown in FIG. 1. The base 22 is a plate made of corrosion-resistant material. The elastic device 24 is a corrosion-resistant elastic ring, such as an O-ring, provided between the base 22 and the wafer 10. The fixing device 26 has a plurality of springs, provided on the base 22 for applying force to the elastic device 24 toward the wafer 10, so that the elastic device 24 is compressed and deformed, providing a seal between the etching fluid 60 and the specific area. The corrosion-resistant material of the base 22 and the elastic device 24 should be compatible with the etching fluid 60. For example, the base 22 is made of Teflon when alkali fluids such as KOH or TMAH are applied as the etching fluid 60.

Further, the pressure modulating device in this embodiment is a connecting pipe 30, provided on the body and connecting the isolated cavity 50 to the external environment to modulate the pressure in the isolated cavity 50.

It should be noted that the fixing device 26 of the wafer protection device of the present invention applies force to the elastic device 24 toward the wafer 10, providing a seal. Further, the pressure modulating device is connected to the isolated cavity 50 to modulate the pressure in the isolated cavity 50. That is, neither the fixing device 26 nor the pressure modulating device of the present invention are limited to the device as disclosed in this embodiment.

### THE SECOND EMBODIMENT

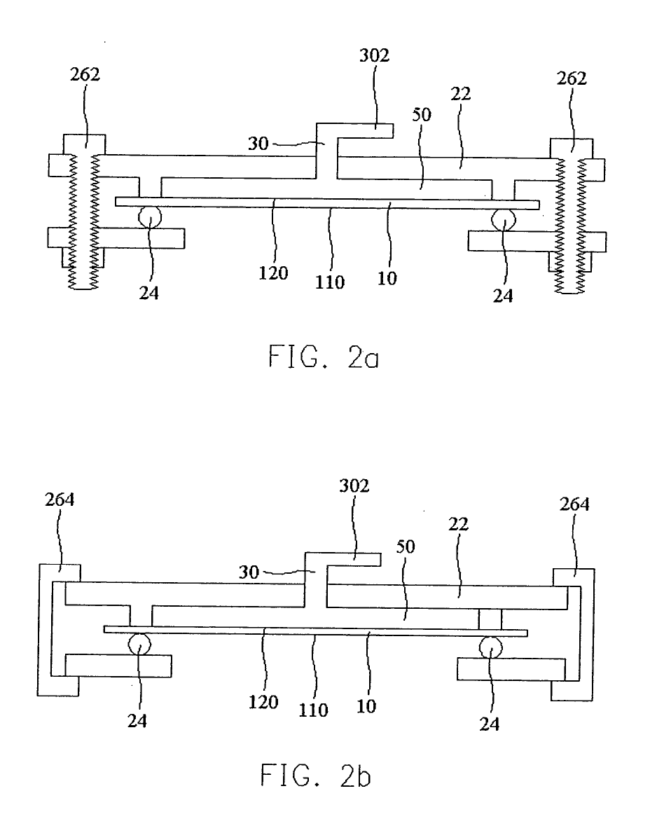

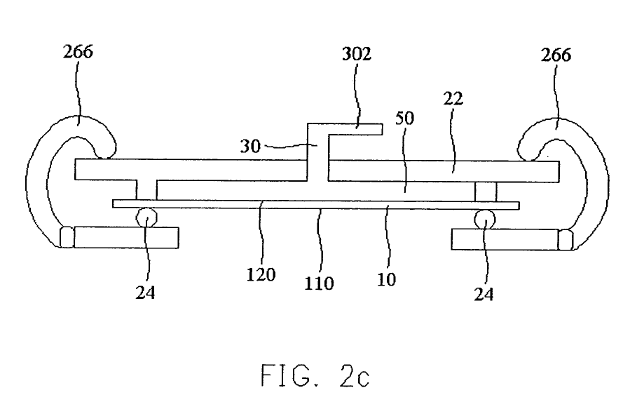

A further embodiment of the wafer protection device of the present invention is hereinafter described in detail with reference to FIG. 2a, in which the fixing device 26 differs from that of the first embodiment. The other components of the wafer protection device in this embodiment are the same as the first embodiment and description thereof is thus omitted.

In this embodiment, a plurality of screw bolts 262 is applied as the fixing device 26. When the screw bolts 262 are screwed onto the body 22, a compressing force is applied on the elastic device (that is, the O-ring) 24, providing a seal.

Further, in this embodiment, the pressure modulating device is a connecting pipe 30, similar to the pressure modulating device in the first embodiment; however, the connecting pipe 30 in this embodiment has a bent portion 302 therein so that the wafer protection device is arranged side by side in a stack to reduce the stack volume.

### THE THIRD EMBODIMENT

A further embodiment of the wafer protection device of the present invention is hereinafter described in detail with reference to FIG. 2b, in which the fixing device 26 differs from that of the first embodiment. Description of other components in this embodiment is thus omitted.

In this embodiment, a plurality of U-shaped clamps 264 is applied as the fixing device 26. When the U-shaped clamps 264 clamp the body 22, a compressing force is applied on the elastic device (that is, the O-ring) 24, providing a seal.

Further, in this embodiment, the pressure modulating device is a connecting pipe 30 with a bent portion 302 therein similar to the connecting pipe 30 in FIG. 2a.

### THE FOURTH EMBODIMENT

A further embodiment of the wafer protection device of the present invention is hereinafter described in detail with reference to FIG. 2c, in which the fixing device 26 differs from that of the first embodiment. Description of the other components of the wafer protection device in this embodiment is omitted.

In this embodiment, a plurality of retaining rings 266 is applied as the fixing device 26. When the retaining rings 266 retain the body 22 to the wafer 10, a compressing force is applied on the elastic device (that is, the O-ring) 24, providing a seal.

Further, in this embodiment, the pressure modulating device is a connecting pipe 30 with a bent portion 302 therein similar to the connecting pipe 30 in FIG. 2a.

### THE FIFTH EMBODIMENT

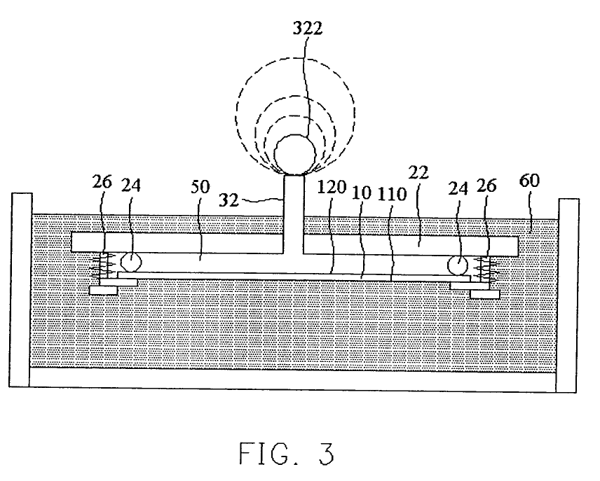

A further embodiment of the wafer protection device of the present invention is hereinafter described in detail with reference to FIG. 3, in which the pressure modulating device in this embodiment differs from the connecting pipe 30 in the first to fourth embodiments. The other components of the wafer protection device in this embodiment are the same as the first embodiment as shown in FIG. 1, and description thereof is thus omitted.

In this embodiment, the pressure modulating device is a sealed pipe 32 with an elastic membrane 322 as a seal. The sealed pipe 32 is connected to the isolated cavity 50, so that the isolated cavity 50 and the interior space of the sealed pipe 32 become airtight, and the elastic membrane 322 of the sealed pipe 32 is inflated or deflated to modulate the pressure in the isolated cavity 50.

### THE SIXTH EMBODIMENT

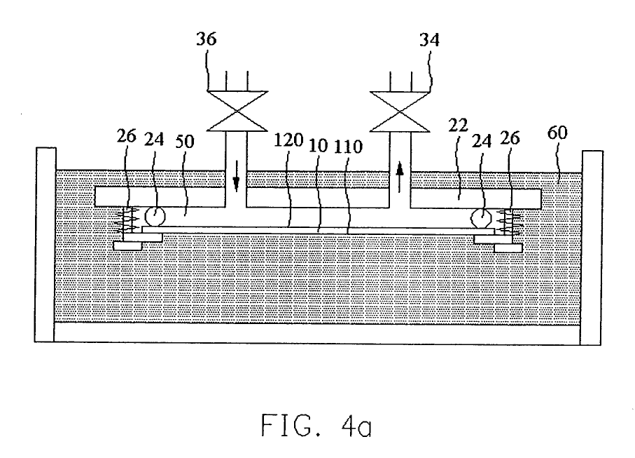

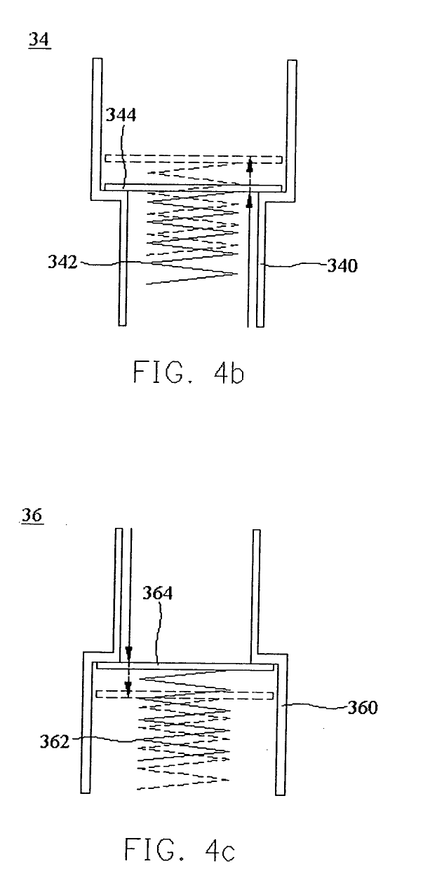

A further embodiment of the wafer protection device of the present invention is hereinafter described in detail with reference to FIG. 4a, in which the pressure modulating device in this embodiment differs from the connecting pipe 30 in the first to fourth embodiments. The other components of the wafer protection device in this embodiment are the same as the first embodiment as shown in FIG. 1, and description thereof is thus omitted.

In this embodiment, the pressure modulating device has an outlet valve 34 and an inlet valve 36. An example of the outlet valve 34 is shown in FIG. 4b, and an example of the inlet valve 36 is shown in FIG. 4c.

The outlet valve 34 in FIG. 4b has a spring 342 and a one-way outward valve 344 that unidirectionally connects the isolated cavity 50 to the external environment. Further, the inlet valve 36 in FIG. 4c has a spring 362 and a one-way inward valve 364 that unidirectionally connects the external environment to the isolated cavity 50.

In the etching process, the pressure in the isolated cavity 50 increases when the temperature increases. When the pressure in the isolated cavity 50 is higher than the external environment pressure, the outlet valve 34 discharges a portion of gas in the isolated cavity 50 to reduce the pressure. On the other hand, when the etching process ends, the pressure in the isolated cavity 50 decreases when the temperature decreases. When the pressure in the isolated cavity is lower than the external environment pressure, the inlet valve 36 takes in air from the external environment to increase the pressure in the isolated cavity 50. In this case, the pressure in the isolated cavity 50 is modulated by the outlet valve 34 and the inlet valve 36.

It should be mentioned that the spring 342 of the outlet valve 34 and the spring 362 of the inlet valve 36 is adjusted to keep the pressure in the isolated cavity 50 in a range near that of the external environment. For example, the springs 342 and 362 can be adjusted so that the pressure in the isolated cavity 50 has a tolerance of 5% in relation to the external environment pressure.

### THE SEVENTH EMBODIMENT

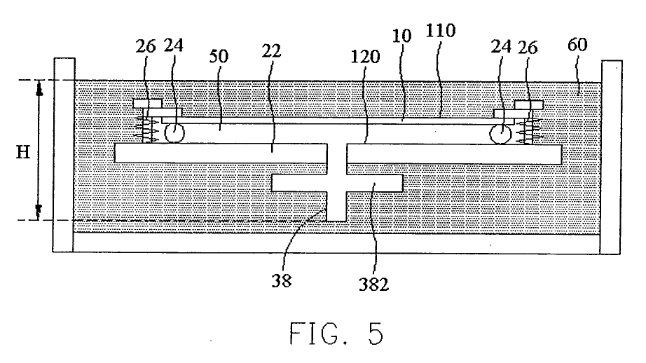

A further embodiment of the wafer protection device of the present invention is hereinafter described in detail with reference to FIG. 5, in which the pressure modulating device in this embodiment differs from the connecting pipe 30 in the first to fourth embodiments. The other components of the wafer protection device in this embodiment are the same as the first embodiment as shown in FIG. 1, and description thereof is thus omitted.

In this embodiment, the pressure modulating device is a downwardly provided conduit 38 that connects the isolated cavity 50 to the etching fluid 60. The opening of the conduit 38 is positioned below the surface of the etching fluid 60 with a depth of H, and a fluid storage portion 382 is provided in the conduit 38.

In the etching process, the pressure in the isolated cavity 50 increases with the temperature. When the pressure in the isolated cavity 50 is higher than a predetermined pressure, gas in the isolated cavity is discharged to the etching fluid through the conduit 38 to reduce the pressure. On the other hand, when the etching process ends, the pressure in the isolated cavity 50 decreases with the temperature. When the pressure in the isolated cavity 50 is lower than the predetermined pressure, the etching fluid 60 is taken into the conduit 38 and stored in the fluid storage portion 382, so that the gas in the isolated cavity 50 occupies a relatively smaller volume and is kept in the predetermined pressure. Thus, the conduit 38 controls the volume of the isolated cavity 50 by taking in the etching fluid 60 to modulate the pressure in the isolated cavity 50.

It should be noted that the fluid storage portion 382 is provided so that the etching fluid 60 does not accidentally enter the isolated cavity 50 while being taken into the conduit 38. The volume of the fluid storage portion 382 is determined in relation to the isolated cavity 50.

It should be mentioned that the above-mentioned embodiments of the present invention is modified or preferably combined in application. For example, the wafer protection device may have a plurality of screw bolts as in the second embodiment as the fixing device 26 of the body while applying the outlet valve 34 and the inlet valve 36 from the sixth embodiment as the pressure modulating device at the same time.

The wafer protection device of the present invention is applied in a method of etching a wafer. When a wafer 10 is provided to be etched, a wafer protection device, such as one in any of the above-mentioned embodiments, is provided for the wafer 10. The wafer 10 is then positioned on the wafer protection device, such that a specific area on the wafer 10, such as the circuit layout on the second surface 120 of the wafer 10, is protected by the wafer protection device. Then, the wafer protection device with the wafer 10 thereon is disposed into the etching fluid 60 for etching. At this time, the wafer protection device protects the specific area on the wafer 10 from etching. Further, since the wafer protection device has the pressure modulating device, such as the connecting pipe 30 in the above-mentioned first embodiment, the interior pressure of the wafer protection device is optimally modulated. Thus, the pressure in the isolated cavity is kept within a predetermined range regardless of the temperature, and the wafer 10 in etching is prevented from fracture or creeping fatigue due to the pressure change.

While the present invention has been described with reference to the preferred embodiments thereof, it is to be understood that the invention is not limited to the described embodiments or constructions. On the contrary, the invention is intended to cover various modifications and similar arrangements as is apparent to those skilled in the art. Therefore, the scope of the appended claims should be accorded the broadest interpretation so as to encompass all such modifications and similar arrangements.

1-15. (canceled)

16. A method of etching a wafer, comprising the steps of:
providing a wafer protection device for the wafer;
positioning the wafer on the wafer protection device;
disposing the wafer protection device into an etching fluid, wherein the wafer protection device protects a specific area on the wafer from etching; and
modulating the interior pressure of the wafer protection device.

17. The method according to claim 16, wherein the wafer protection device comprises a connecting pipe connecting the interior of the wafer protection device to the external environment to modulate the interior pressure of the wafer protection device.

18. The method according to claim 16, wherein the wafer protection device comprises a sealed pipe with an elastic membrane, the elastic membrane inflated or deflated to modulate the interior pressure of the wafer protection device.

19. The method according to claim 16, wherein the wafer protection device comprises:
an outlet valve unidirectionally connecting the interior of the wafer protection device to the external environment to reduce the interior pressure of the wafer protection device when the interior pressure of the wafer protection device is higher than the external environment pressure; and
an inlet valve unidirectionally connecting the external environment to the interior of the wafer protection device to increase the interior pressure of the wafer protection device when the interior pressure of the wafer protection device is lower than the external environment pressure,
thereby modulating the interior pressure of the wafer protection device.

20. The method according to claim 16, wherein the wafer protection device comprises:
a conduit connecting to the etching fluid,
wherein gas in the wafer protection device is discharged to the etching fluid through the conduit when the interior pressure of the wafer protection device is higher than a predetermined pressure, and
wherein the etching fluid is taken into the conduit when the interior pressure of the wafer protection device is lower than the predetermined pressure, thereby modulating the interior pressure of the wafer protection device.

21. The method according to claim 20, wherein the conduit comprises a fluid storage portion for storing the etching fluid taken into the conduit.
